(19) United States
(12) Patent Application Publication
(10) Pub. No.: US 2003/0015132 A1
(43) Pub. Date: Jan. 23, 2003

(54) Stackable vapor-equilibration tray for cell culture and protein crystal growth

(76) Inventor: Daniel C. Carter, Madison, AL (US)

Correspondence Address: LARSON & TAYLOR, PLC, 1199 NORTH FAIRFAX STREET, SUITE 900, ALEXANDRIA, VA, 22314, US

(21) Appl. No.: 09/909,843

(22) Filed: Jul. 23, 2001

(51) Int. Cl. C30B 7/00; C30B 21/02; C30B 28/06

(52) U.S. Cl. 117/68

(57) ABSTRACT

An apparatus and method for growing protein crystals or performing other chemical or biological processes, such as the culturing of cells, fungi or bacteria, is provided wherein a stackable tray containing sealable wells for housing a coverslip and a protein solution or other desired biological materials has side walls which extend to provide a base so that the tray may be stacked upon a tray below it, but wherein the sealable wells have a raised bottom which does not extend the same distance and thus are raised above the upper surface of the tray below it. By virtue of the present apparatus, the need to provide a plastic lid on the tray upon which another tray will be stacked is eliminated, and this makes these trays cheaper and more efficient, and allows them to be far more readily handled using robotics or other automated systems to stack, unstack, or manipulate the trays.

### BACKGROUND OF THE INVENTION

1. Field of the Invention

The present invention relates in general to an apparatus suitable for use in growing protein crystals and in culturing of cells and other biological materials, and more particularly to a stackable tray for growing protein crystals or for other chemical, physical, or biological processes which has wells for performing a protein crystallization process or other chemical or physical reaction, or for performing a biological process such as culturing of cells, fungi or bacteria, which have a raised bottom so as to allow for stacking of the trays without the use of a plastic lid to cover the wells.

2. Description of the Related Art

In the field of protein crystallization, there have been many devices which have been utilized in methods to achieve crystal protein growth. The most prevalent method used for performing protein crystal growth typically involves filling the wells of a plastic tray with a buffered solution and a precipitating agent, then sealing the well with an inverted glass coverslip having a small (e.g., 5 to 10 microliter) protein solution droplet hanging from its surface. This is commonly referred to in the art as the hanging-drop vapor-equilibration method. The plastic trays used with this method come in variety of shapes and sizes. Prior art trays and other apparatuses used to achieve protein growth have been disclosed in numerous patents, including U.S. Pat. Nos. 5,643,540; 5,419,278; 5,130,105; 5,096,676; and 5,078,975, all incorporated herein by reference.

In addition, there have been trays which have been used in culturing of biological materials, such as cells, fungi or bacteria, but these trays also generally require the presence of some type of lid to protect the culturing well from the impingement of the well in a tray above it before it can be adequately stacked.

In apparatuses for performing protein crystallizations, it is also well known in the art to use silicon grease and vacuum oil to seal the glass coverslip to the tray when performing protein crystal growth. This is shown, for example, in U.S. Pat. No. 4,495,289, incorporated herein by reference, which discloses a method of protein growth which requires the inverting and sealing of each well with silicon grease. In these apparatuses, once the wells are sealed, it is necessary to use plastic lids to cover trays in order to stack them, and this can be disadvantageous because the lid may contact the surface of the coverslip and cause, among other things, breakage as well as smearing of the grease or vacuum oil. These occurrences can thus endanger the protein growth and/or experiments being carried out in this devices. Another disadvantage of using plastic lids is that they must be replaced manually after each examination and during set-up. Therefore, there is a need to provide a tray apparatus that can eliminate these undesirable effects.

Recently, efforts to address this problem include those by Hampton Research which introduced a tray and lid combination which features a lid raised above the surface of the wells. However, while the presence of a raised lid reduces the harmful contact with the coverslip, it still requires the presence of a plastic lid over the raised lid in order for the tray to be stackable, and thus this tray retains all of the problems of the other prior art devices which require a lid in order to be stacked. As a result, the Hampton device does not allow for a fully automated system since the lid must be replaced after each examination and during set up. Moreover, the use of the lid will once again increase the manufacturing costs associated with the tray system.

As a result, there is a distinct need in the field of protein crystal growth and cell culturing to develop an apparatus which can be easily stacked without the use of a plastic lid in multiple trays, and which can thus be utilized safely, efficiently and inexpensively in robotic or automated applications.

### SUMMARY OF THE INVENTION

It is thus an object of the present invention to provide an apparatus for protein crystal growth which eliminates the need for stackable multiple trays to have a plastic lid and which allows the crystal growth tray to be useable in robotic and automated applications.

It is further an object of the present invention is to provide protein growth trays which may be easily stacked upon one another.

It is yet another object of the present invention to provide a protein growth apparatus that may be used with a robotic or other fully automated system for manipulating protein crystal growth trays as well as stacking and unstacking them.

It is still another object of the present invention to provide a stackable protein crystal growth tray that may be used in a microgravity environment.

It is still further an object of the present invention to provide a stackable tray with sealable wells that can be used for carrying out a variety of chemical, physical, and/or biological processes which are most efficiently carried out in sealable wells, such as the culturing of cells, fungi and/or bacteria.

These and other objects are provided by the present invention which comprises a stackable tray containing at least one sealable well for performing a protein crystallization process or other chemical or biological process, such as culturing of cells, fungi, or bacteria, wherein the tray has an upper surface substantially coplanar with an upper opening of the sealable well, and side walls which extend below the bottom surface of the crystallization or culturing wells so that the lower surface of the sealable well does not directly contact the upper surface of a second stackable tray positioned below it. Such a raised-bottom tray will allow the protein crystal growth or biological culturing trays to be stacked on top of another without the use of a plastic lid, and the present invention is advantageous in that it will allow a stack of these trays to be utilized in a robotic or fully automated system of stacking, unstacking, and manipulating the trays.

Further features and advantages of the present invention will be set forth in, or apparent from, the detailed description of the preferred embodiments following below.

### BRIEF DESCRIPTION OF THE DRAWINGS

The foregoing objects and advantages of the present invention for a new and improved stackable tray apparatus, and method for utilizing this tray to conduct experiments, perform chemical processes including protein crystallization, or perform biological processes such as the culturing of bacteria, fungi, and/or cells, including the possibility of performing such processes in microgravity environments, will be more readily understood by one skilled in the art by referring to the following detailed description of the preferred embodiments and to the accompanying drawings which form part of this disclosure, and wherein:

FIG. 1 is an perspective view of a stackable raised-bottom tray in accordance with a preferred embodiment of the present invention.

FIG. 2a is a front cross-sectional view along lines A-A of the tray as shown in FIG. 1.

FIG. 2b is a side cross-sectional view along lines B-B of the tray as shown in FIG. 1.

FIG. 3 is an perspective view of a stack of raised-bottom trays in accordance with a preferred embodiment of the present invention.

FIG. 4 is an side cross-sectional view of a stack of raised-bottom trays in accordance with a preferred embodiment of the present invention.

### DETAILED DESCRIPTION OF THE PREFERRED EMBODIMENTS

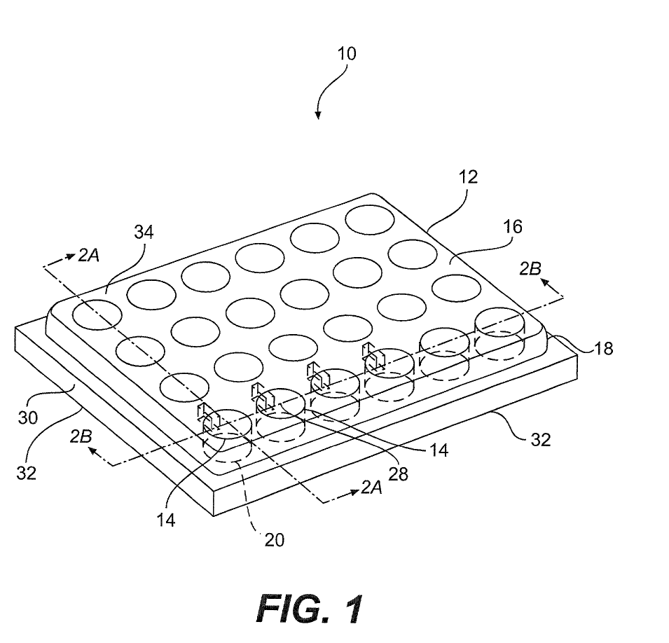

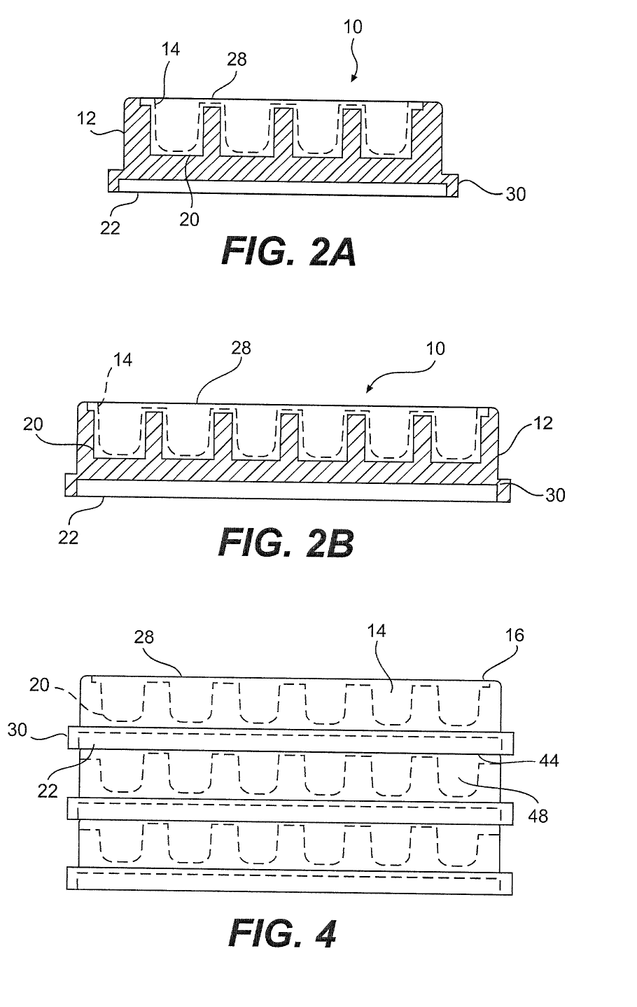

Referring initially to FIG. 1, there may be seen, generally at 10, a preferred embodiment of a stackable apparatus in accordance with the present invention which is suitable for use in growing protein crystals or for performing other chemical, physical, or biological processes in a sealed well. The apparatus includes a stackable tray 12 containing at least one sealable well 14 for performing a protein crystallization process or other chemical or biological process, such as a culturing process for biological materials such as cells, fungi, or bacteria, as would be known to those skilled in the art. The tray 12 has an upper surface 16 substantially coplanar with an upper opening 28 in the sealable well 14, and side walls 18 extending beyond a lower surface 20 of the sealable well 14. This is also shown in the cross-sectional views of the stackable tray 10 of the invention in FIGS. 2a and 2b. As can be observed in FIGS. 1 and 2a-2b, the side walls 18 have a lower end 22 configured so as to allow the tray 12 to be stacked on top of a second tray 42, as described further below. In one preferred embodiment, the lower ends of side walls 18 forms a base 30 which suitably can be placed upon the top of a second tray when placed below it and allows the stacking of multiple trays 10. In the particularly preferred embodiment, the base 30 will comprise four side walls 32 at the perimeter of the tray 12 which are sized so as to fit snugly over the outer portion 44 of the upper surface of a second tray 42 positioned below a first tray as described below. In this manner, the upper openings 28 of wells 14 are not directly impinged by the lowermost point of the wells of the tray on top of it, and thus these trays can carry out protein crystal growth processes or cell culturing processes without the need for an extra plastic lid to protect the wells and the biological or chemical processes occurring therein from harm or disruption by a tray stacked on top of it.

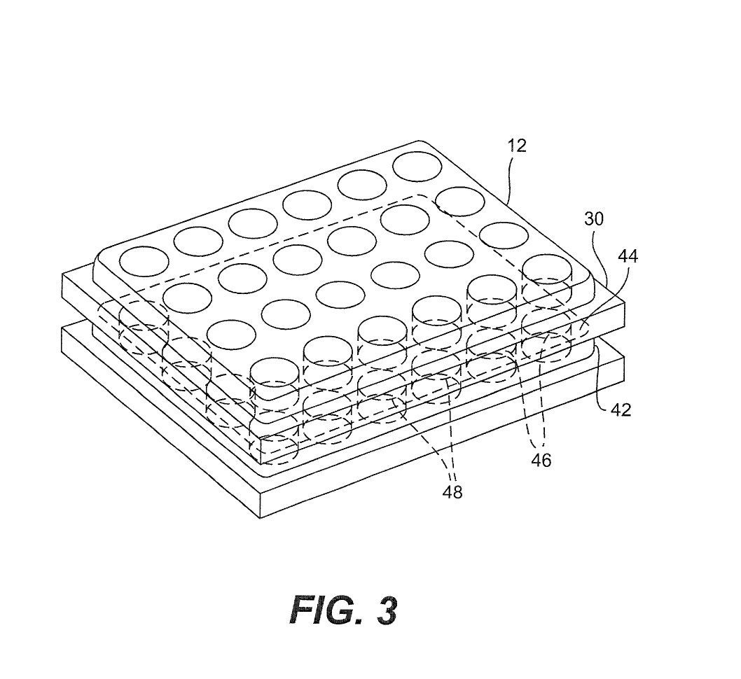

As shown in FIGS. 3 and 4, in the preferred embodiment, the stacked tray 10 of the present invention having a raised bottom may be stacked without the need for a plastic lid or other covering over the upper openings 16 of the wells of the trays of the present invention. As shown in FIG. 3, in operation, a first tray 12 is stacked upon a second tray 42 so that the base 30 of tray 12 snugly fits over the outer portion 44 of lower tray 42. In this case, the lowermost point 20 of the wells 14 in the upper tray 12 are spaced apart from the upper openings 46 of the wells 48 of the lower tray 42, and thus culturing processes or protein crystallization methods, such as the hanging drop method, may be carried out in the lower tray without any need for a lid to protect the wells from being contacted by the upper tray 12.

The apparatus of the present invention may be made of any material that has suitably been used for protein crystallization or biological culturing methods, such as those materials disclosed in U.S. Pat. Nos. 5,643,540; 5,419,278; 5,130,105; 5,096,676; and 5,078,975, all incorporated herein by reference. Included in these materials are any of the sturdy, transparent hard plastics, e.g., moldable plastics such as polystyrene or polycarbonates, but other suitable materials such as glass, polysulphone or polypropylene may also be utilized in accordance with the invention. In addition, because zero-gravity environments have been shown to be optimal for protein crystal growth, the materials used in the present invention should also be sturdy enough to withstand the conditions associated with achieving and maintaining a zero- or low-gravity environment should it be desired to utilize the tray in a microgravity environment. Further, the tray may be manufactured by any suitable means known in the art for making such plastic trays including, for example, one-piece injection molding or other molding or forming operations which would be known to one skilled in the art.

In accordance with the present invention, protein crystallization processes or biological culturing processes, such as the culturing of cells, fungi, or bacteria, may be readily and more efficiently accomplished using the apparatus of the present invention. For example, the present stackable tray may be utilized in order to carry out protein crystal growth, and a number of suitable processes, such as the traditional hanging-drop method as described above or in numerous patents including the patents disclosed above and incorporated herein by reference, may be used with the tray of the present invention. In this method, a drop of protein growth solution is placed on a coverslip which is placed upside down on top of a well and is sealed tightly by a silicone grease, following which the protein crystallization procedures are allowed to take place. Using the stackable trays of the present invention, each tray will preferably have a plurality of wells disposed in the tray, e.g., a 4×6 pattern which thus has 24 wells in a single tray, and thus having a stack of these trays will allow a large number of crystal growth operations to be carried out at one time. Moreover, because the stackable tray of the present invention does not require a lid before the trays can be stacked, the trays of the present invention will be far more easily utilized in automated apparatuses, such as robotic devices, used to stack, unstack and manipulate the crystal growth trays during a protein crystallization procedure, or any other chemical reaction that may be suitably carried out in the wells of trays of the present invention.

Similarly, a number of biological culturing methods may be utilized in accordance with the invention as would be readily understood by one skilled in the art, and these methods include the culturing of biological materials such as cells, fungi and bacteria.

In accordance with the present invention, it is thus possible to have a method of performing protein crystallization, or other chemical reactions or biological reactions such as culturing of biological materials, by utilizing the stackable tray as described above, wherein the materials necessary to perform such protein crystallizations or other chemical or biological reactions are placed in the wells of the trays, and coverslips placed over the wells of the trays where necessary, and the trays may be stacked so as to maximize the number of protein crystallization events or other chemical or biological processes that can take place without the need for plastic lids which would hamper efforts to perform such methods using automated apparatuses or robotics.

Although the invention has been described above in relation to preferred embodiments thereof, it will be understood by those skilled in the art that variations and modifications can be effected in these preferred embodiments without departing from the scope and spirit of the invention.

What is claimed is:

1. An apparatus suitable for use in carrying out a chemical or biological process comprising:
a stackable tray containing at least one sealable well in which a chemical or biological process may be performed, said tray having an upper surface substantially coplanar with an upper opening in said sealable well, and side walls extending beyond the lowermost surface of said sealable well, said side walls having a lower end configuration so as to form an outer base capable of allowing said tray to be stacked on the outer portion of the upper surface of a second stackable tray positioned below the first tray while maintaining separation between the upper openings of the second stackable tray and the lower surface of the sealable wells of the first stackable tray so as to allow stacking of said trays without a lid to prevent impingement of the upper well openings by the lower surface of the first tray.

2. The apparatus of claim 1 wherein said apparatus is capable of performing a protein crystallization process.

3. The apparatus of claim 1 wherein said apparatus is capable of performing a process of culturing a biological material.

4. The apparatus of claim 3 wherein said biological material is selected from the group consisting of cells, fungi and bacteria.

5. The apparatus of claim 1 wherein said sealable well is sealable with clear plastic tape.

6. The apparatus of claim 1 further comprising an automated system for stacking and unstacking said stackable trays.

7. The apparatus of claim 2 wherein the protein crystallization process comprises a hanging-drop vapor-equilibration method.

8. The apparatus of claim 1 wherein the tray is comprised of a material selected from the group consisting of plastic and glass.

9. The apparatus of claim 1 further comprising a solution capable of forming crystals within said well.

10. The apparatus of claim 1 further comprising a second stackable tray stacked below said first tray.

11. A method for performing a chemical or biological process comprising the steps of: providing a plastic tray, the tray having an upper surface substantially coplanar with an upper opening in the sealable well, and side walls extending beyond a lower surface of the sealable well, said side walls having a lower end configured so as to allow the tray to be stacked on top of another stackable tray with said lower surface of said sealable well disposed at a position raised above the upper surface of the other tray stacked below thereby allowing stacking interactions without the use of a plastic lid; and performing the chemical or biological process in the sealable well of the tray.

12. The method of claim 11 wherein the chemical process comprises protein crystallization.

13. The method of claim 12 wherein the protein crystallization is carried out using the hanging-drop method.

14. The method of claim 11 wherein the biological process comprises culturing of a biological material.

15. The method of claim 14 wherein the biological material is selected from the group consisting of cells, fungi and bacteria.

16. An apparatus suitable for use in growing protein crystals, said apparatus comprising: a stackable tray containing at least one sealable well for performing a protein crystallization process, said tray having an upper surface substantially coplanar with an upper opening in said sealable well, and side walls extending beyond a lower surface of said sealable well, said side walls having a lower end configured so as to allow said tray to be stacked on top of another stackable tray with said lower surface of said sealable well disposed at a position raised above said upper surface of the other tray stacked below thereby allowing stacking of the trays without the lowermost surface of the wells of the upper tray contacting the upper openings of the wells of the tray below it.
